(19) United States
(12) Patent Application Publication
(10) Pub. No.: US 2003/0143817 A1
(43) Pub. Date: Jul. 31, 2003

(54) Method of forming shallow trench isolation

(76) Inventors: Tzu En Ho, Ilan (TW); Yi-Nan Chen, Taipei (TW); Chang Rong Wu, Banchiau City (TW)

Correspondence Address: MERCHANT & GOULD PC, P.O. BOX 2903, MINNEAPOLIS, MN, 55402-0903, US

(21) Appl. No.: 10/159,934

(22) Filed: May 29, 2002

(30) Foreign Application Priority Data
Jan. 28, 2002 (TW) 91101349

(51) Int. Cl. H01L 21/76

(52) U.S. Cl. 438/435

(57) ABSTRACT

A method for manufacturing a shallow trench isolation. A pad oxide layer and a nitride layer are sequentially deposited on a substrate. The nitride layer and the pad oxide layer are patterned to expose the substrate. Thereafter, the exposed substrate is etched to form a plurality of trenches. A lining oxide layer is formed on the surface of the trenches. Subsequently, a first oxide layer is formed by high-density plasma chemical vapor deposition (HDPCVD) into the trenches and over the surface of the nitride layer. Next, the first oxide layer at the top of the trenches is removed by spin etching. Then, a second oxide layer is formed by the high-density plasma chemical vapor deposition (HDPCVD) to fill out the plurality of trenches and cover the surface of the nitride layer. The excess portion of the second oxide layer over the nitride layer, the nitride layer and the pad oxide layer are removed sequentially.

### BACKGROUND OF THE INVENTION

1. Field of the Invention

The present invention relates in general to a method of forming a shallow trench isolation. In particular, the present invention relates to an improved method of forming a shallow trench isolation using high-density plasma chemical vapor deposition and spin etching that improves the gap-filling effect of oxide layer.

2. Description of the Related Art Recently, with the fast development of semiconductor process technology, the dimensions of integrated circuits (ICs) have rapidly scaled down into quarter-micron level. A complete integrated circuit is composed of a plurality of metal oxide semiconductor (MOS) transistors. Device isolation structures are used for isolating neighboring semiconductor devices so that any short-circuiting between them is prevented. The conventional method of isolating semiconductor devices includes forming a field oxide (FOX) layer on a substrate by local oxidation of silicon (LOCOS). However, the field oxide layer that is formed has several problems. Considerable stresses are created at the junction between the field oxide layer and the substrate. Moreover, bird's beak regions are created around the periphery of the isolation structure. Consequently, IC devices that use (FOX) isolation structures are less amenable to high-density packing.

Shallow trench isolation is another method for isolating semiconductor devices. Shallow trench isolation entails the following procedures. First an anisotropic etching operation is conducted to form a trench in semiconductor substrate. The trench is subsequently filled with silicon oxide. Since shallow trench isolation can prevent bird's beak encroachment associated with the LOCOS method, it is an ideal method for forming sub-micron devices.

In the conventional shallow trench isolating method, a dielectric layer is formed into the trench within the substrate using a chemical vapor deposition (CVD) process. Afterwards, the excess portion of the dielectric layer over the substrate is removed by an etching back process or a chemical mechanical polish process (CMP). Thereby a shallow trench isolation is formed. Recently, a high-density plasma chemical vapor deposition (HDPCVD) is used to form a dielectric layer on the substrate for instead of the chemical vapor deposition (CVD) process.

FIGS. 1A˜1G illustrate cross-sectional views of a convention method for fabricating shallow trench isolation.

First, as shown in FIG. 1A, a pad oxide layer 4 is formed on the surface of a silicon substrate 2 by thermal oxidation. For example, the pad oxide layer 4 is a silicon oxide layer. A silicon nitride layer 6 is subsequently deposited on the pad oxide layer 4 using a chemical vapor deposition (CVD) process.

Further, the element isolation region is defined by coating a resist layer 8 on the silicon nitride layer 6 and patterning the resist layer 8 by a photolithography process, as shown in FIG. 1B. For example, the photolithography process includes resist coating process, resist exposure process and development process. After that, the silicon nitride layer 6 and the pad oxide layer 4 are etched to exposure the element isolation of the substrate 2 using the resist layer 8 as a mark, as shown in FIG. 1C.

Next, the resist layer 8 is stripped using a suitable solution. A plurality of trenches 10 is formed in the silicon substrate 2 using the silicon nitride layer 6 and the pad oxide layer 4 as a mark layer and then etching the silicon substrate 2, as shown in FIG. 1D.

Afterwards, an oxide layer 14 is deposited into the trenches 10 and cover the surface of the silicon nitride 6 using a high-density plasma chemical vapor deposition (HDPCVD) process, as shown in FIG. 1E. For example, the oxide layer 14 is a silicon oxide layer whose thickness is 4500 Å.

Subsequently, the excess portion of the oxide layer 14 over the silicon nitride layer 6 is removed by a chemical mechanical polish process (CMP), as shown in FIG. 1F. Finally, the silicon nitride 6 and the pad oxide layer 4 are removed using wet etching or dry etching. Therefore, a shallow trench isolation 14a is formed, as shown in FIG. 1G.

However, due to that scaled down density and dimensions of integrated circuits (ICs), i.e., 0.11 micron or deeper, the dielectric layer can not easily fill the entire trench, thereby decreasing the efficiency of the element isolation. As shown in FIG. 2, the oxide layer 24 deposed on the silicon nitride layer 6 may cover the opening of the trenches in the high-density plasma chemical vapor deposition (HDPCVD) process, thereby the oxide layer 24 can not fill out the trench completely.

### SUMMARY OF THE INVENTION

The present invention provides a method of forming a shallow trench isolation. The method of the present invention can fill out the trench completely using multi-step deposition of HDPCVD process accompanied by spin etching for removing the oxide layer covering the opening of the trenches.

In the method of the present invention, a pad oxide layer and a nitride layer are sequentially deposited on a substrate. The nitride layer and the pad oxide layer are patterned to expose the substrate. Thereafter, the exposed substrate is etched to form a plurality of trenches. A lining oxide layer is formed on the surface of the trenches. Afterwards, a first oxide layer is formed by a high-density plasma chemical vapor deposition (HDPCVD) on the trenches and the surface of the nitride layer. Next, the first oxide layer at the top of the trenches is removed by a spin etching. Then, a second oxide layer is formed by high-density plasma chemical vapor deposition (HDPCVD) to fill out the plurality of trenches and cover the surface of the nitride layer. The excess portion of the second oxide layer over the nitride layer, the nitride layer and the pad oxide layer are removed sequentially.

### BRIEF DESCRIPTION OF THE DRAWINGS

The present invention can be more fully understood by reading the subsequent detailed description in conjunction with the examples and references made to the accompanying drawings, wherein:

FIGS. 1A˜1G illustrate cross-sectional views of a convention method for fabricating shallow trench isolation;

FIG. 2 is a cross-sectional diagram of conventional shallow trench isolation with voids;

FIGS. 3A˜3I illustrate cross-sectional views of a method for fabricating shallow trench isolation according to the present invention.

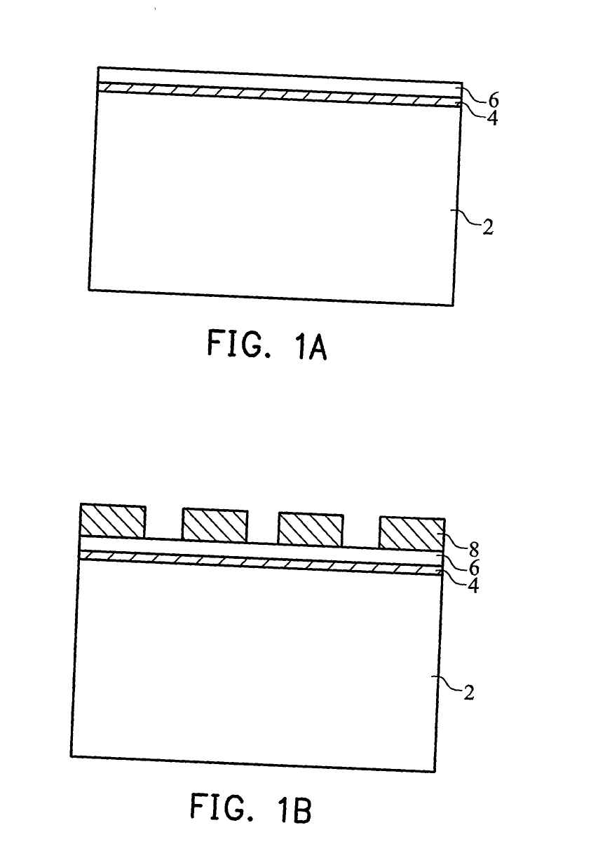

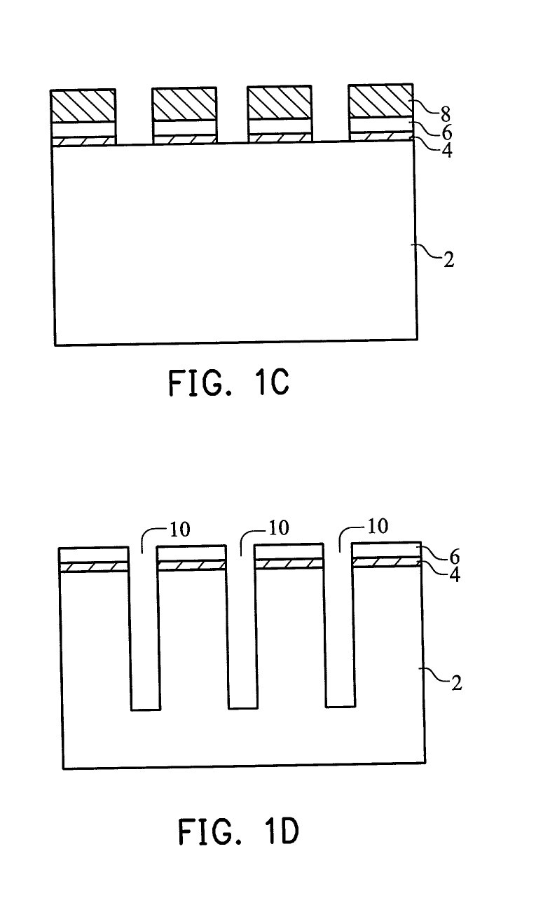

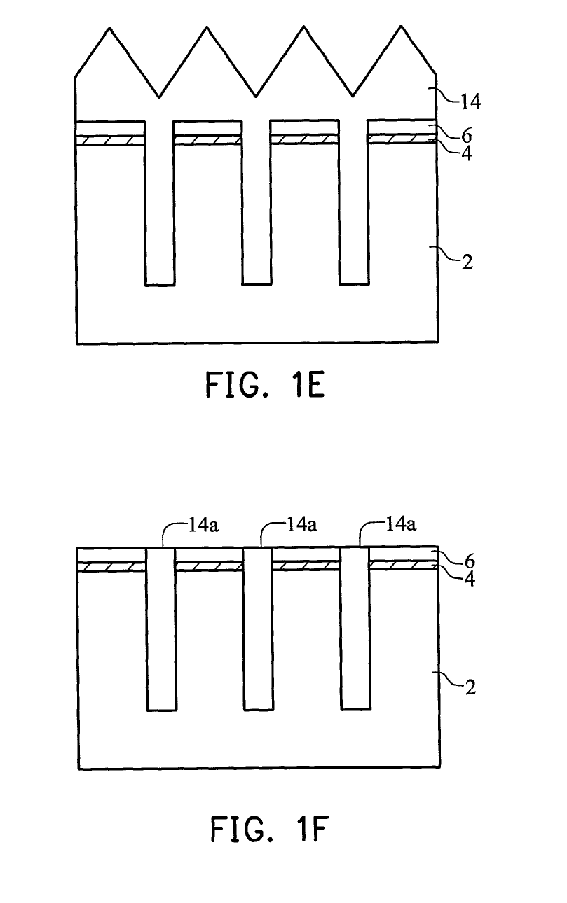

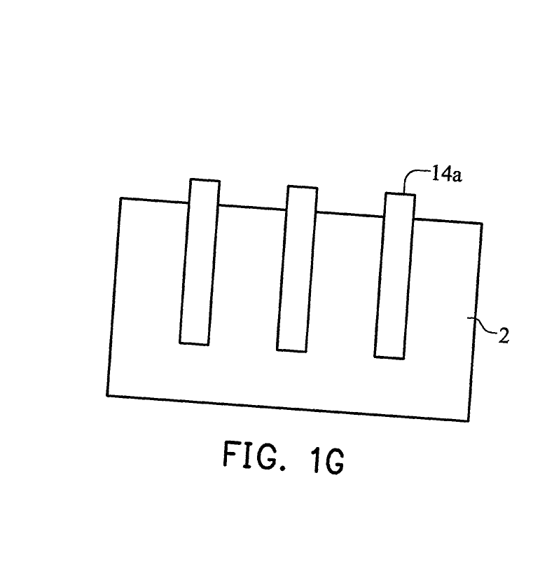

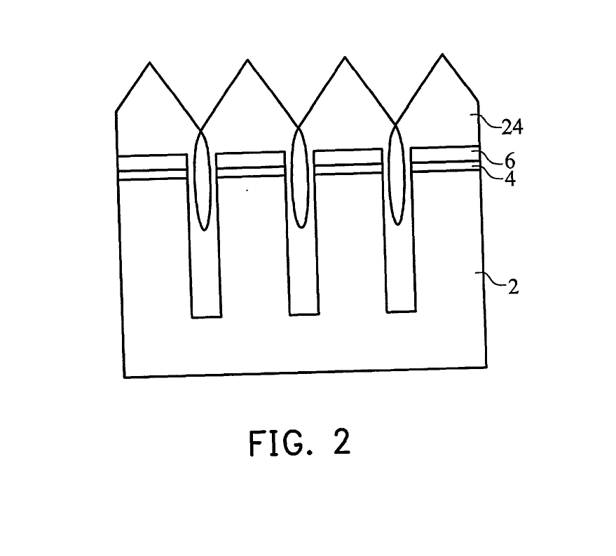

### DETAILED DESCRIPTION OF THE PREFERRED EMBODIMENT

Embodiments of the present invention will be described below with reference to the drawings.

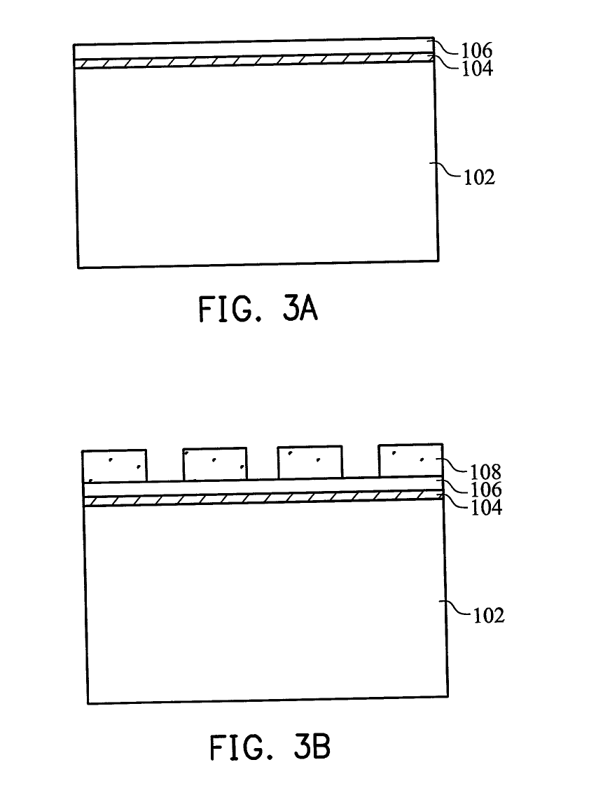

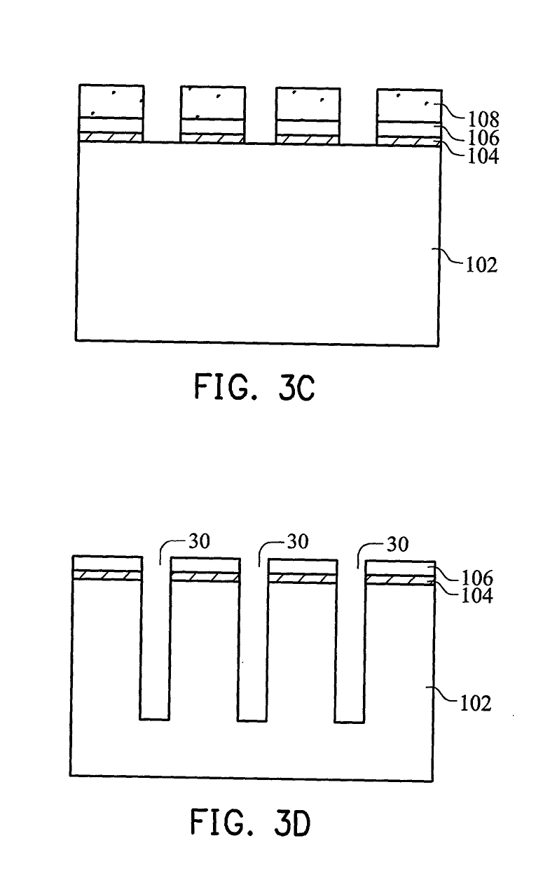

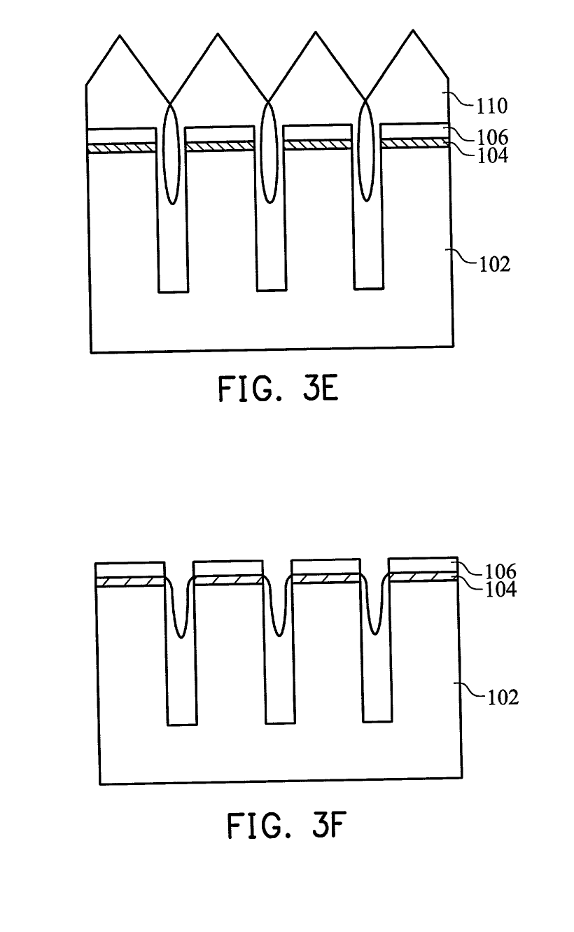

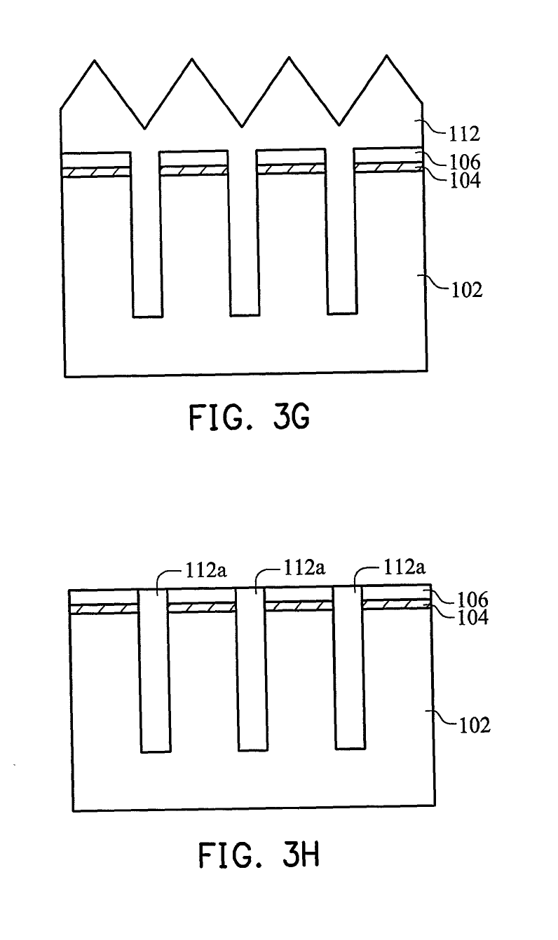

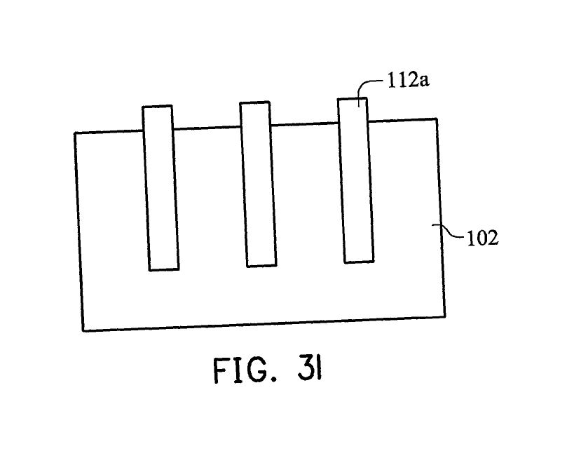

FIGS. 3A˜3I illustrate cross-sectional views of a method for fabricating shallow trench isolation according to the present invention.

First, as shown in FIG. 3A, a pad oxide layer 104 is formed on the surface of a silicon substrate 102 by thermal oxidation or chemical vapor deposition (CVD). For example, the pad oxide layer 104 is a silicon oxide layer whose thickness is between 50˜60 Å. A silicon nitride layer 106 is subsequently deposited on surface of the pad oxide layer 104 using a chemical vapor deposition (CVD) process, as shown in FIG. 3B. For example, the silicon nitride layer 106 has a thickness between 1000˜2000 Å. The pad layer 104 and the silicon nitride layer 106 form a stack layer structure.

Further, an element isolation region is defined by coating a resist layer 108 on the surface of the silicon nitride layer 106 and patterning the resist layer 108 by a photolithography process, as shown in FIG. 3B. The photolithography process can be, for example, a resist coating process, resist exposure process and development process.

Subsequently, the silicon nitride layer 106 and the pad oxide layer 104 are etched to exposure the element isolation of the substrate 102 using the resist layer 108 as a mark, as shown in FIG. 3C.

Next, the resist layer 108 is stripped using a suitable solution. A plurality of trenches 30 are formed in the silicon substrate 102 using the silicon nitride layer 106 and the pad oxide layer 104 as a mark layer and then etching the silicon substrate 102, as shown in FIG. 3D. For example, the depth of the trenches is between 5000˜7000 Å, and the silicon substrate 102 is etched using wet etching or dry etching.

Afterwards, a first oxide layer 110 is deposited into the trenches 30 and over the surface of the silicon nitride 106 using a high-density plasma chemical vapor deposition (HDPCVD) process, as shown in FIG. 3E. For example, the first oxide layer 110 is a silicon oxide layer whose thickness is between 4000˜5000 Å, wherein oxygen (O2) and silane (SiH4) are used to as reactants gases in the HDPCVD process, and then Ar plasma sputtering is performed to deposit the first oxide layer 110 into the trenches 30 and on the surface of the silicon nitride layer 106.

Subsequently, the excess portion of the first oxide layer 110 over the silicon nitride layer 106 and the portion of the first oxide layer 110 at the top of the trenches 30 are removed by a spin etching, as shown in FIG. 3F. In the spin etching process, etching solution only etch the excess portion of the first oxide layer 110 over the silicon nitride layer 106 and the portion of the first oxide layer 110 at the top of the trenches 30 due to the centrifugation is induced by spinning. Thereby, the first oxide layer 110 covered the opening of the trenches 30 is removed and the first oxide layer 110 within lower portion of the trenches is retained.

Then, a second oxide layer 112 is formed by the high-density plasma chemical vapor deposition (HDPCVD) process to fill out the plurality of trenches 30 and cover the surface of the nitride layer 106, as shown in FIG. 3G. For example, the second oxide layer 112 is a silicon oxide layer whose thickness is between 4000˜5000 Å, wherein oxygen (O2) and silane (SiH4) are used to as reactant gases in the HDPCVD process, and then Ar plasma sputtering is performed to deposit the second oxide layer 112 into the trenches 30 and on the surface of the silicon nitride layer 106.

After that, the excess portion of the oxide layer 112 over the silicon nitride layer 106 is removed by a chemical mechanical polish (CMP) process, as shown in FIG. 3H. Finally, the silicon nitride 6 and the pad oxide layer 4 are removed to expose the active region using wet etching or dry etching. For example the silicon nitride layer 106 is stripped by hot phosphoric acid (H₃PO₄) and the pad layer is etched away by hydrofluoric acid (HF). Therefore, a shallow trench isolation 112a of substrate is formed, as shown in FIG. 3I.

It is understood that in the method of forming shallow isolation according to the present invention, the number of repetitions of the deposition and the spin etching steps can be adjusted to remove the oxide layer covering the openings of the trenches. The number of repetitions of the deposition and the spin etching steps is based on the depth and width of the trench, or the thickness of the oxide layer deposited and etching rate of the spin etching.

Moreover, the method of forming shallow trench isolation according to the present invention may further include a step of forming a lining oxide layer on the sidewall and the bottom of the plurality of the trenches before forming the first oxide layer 110. For example, the lining oxide layer is formed by thermal oxidation on the shallow trench sidewalls so that dangling bonds located on the surface of the shallow trench can be effectively repaired.

Therefore, the present invention can use a high-density plasma chemical vapor deposition (HDPCVD) process to fill out the trench effectively by removing the oxide layer covered the opening of the trench using spin etching. Consequently, the present invention can form shallow trench isolations with high aspect ratio and the process is easy to control.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming shallow trench isolation, comprising:
providing a substrate;
depositing a pad oxide layer on the substrate;
depositing a nitride layer on the pad oxide layer;
forming a plurality of openings in the nitride layer and the pad oxide layer to expose the substrate;
forming a plurality of trenches in the substrate using the nitride layer and the pad oxide layer as masks;
depositing a first oxide layer into the plurality of trenches and over the surface of the nitride layer by high-density plasma chemical vapor deposition (HDPCVD);
removing the first oxide layer on the surface of the nitride layer and at the top of the trenches by spin etching;
depositing a second oxide layer to fill out the plurality of trenches and over the surface of the nitride layer by high-density plasma chemical vapor deposition (HDPCVD);
removing the excess portion of the second oxide layer over the nitride layer; and
removing the nitride layer and the pad oxide layer.

2. The method as claimed in claim 1, further comprising:
forming a lining oxide layer on the sidewall and the bottom of the plurality of the trenches before forming the first oxide layer.

3. The method as claimed in claim 1, wherein the nitride layer is formed by a chemical vapor deposition (CVD).

4. The method as claimed in claim 1, wherein the pad oxide layer is formed by a thermal oxidation.

5. The method as claimed in claim 1, wherein the step of removing the excess portion of the second oxide layer over the nitride layer is performed by a chemical mechanical polish (CMP).

5. The method as claimed in claim 1, wherein the thickness of the pad-oxide is between 50˜60 Å.

6. The method as claimed in claim 1, wherein the thickness of the nitride layer is between 1000˜2000 Å.

7. The method as claimed in claim 1, wherein the depth of the trenches is between 5000˜7000 Å.

8. The method as claimed in claim 1, wherein the thickness of the first oxide layer is between 3000˜4000 Å.

9. The method as claimed in claim 1, wherein the high-density plasma chemical vapor deposition is performed using oxygen (O2) and silane (SiH4) as reactants and applying Ar plasma sputtering to dispose the first oxide layer and the second oxide layer.

10. The method as claimed in claim 2, wherein the lining layer is formed by a thermal oxidation.
